(19) United States
(12) Patent Application Publication
(10) Pub. No.: US 2021/0083458 A1
(43) Pub. Date: Mar. 18, 2021

(54) SEMICONDUCTOR OPTICAL AMPLIFIER

(71) Applicant: Open Water Internet Inc., San Francisco, CA (US)

(72) Inventors: Albert P. Heberle, Santa Clara, CA (US); Hosain Haghany, San Francisco, CA (US)

(21) Appl. No.: 17/024,461

(22) Filed: Sep. 17, 2020

Related U.S. Application Data
(60) Provisional application No. 62/901,687, filed on Sep. 17, 2019.

(51) Int. Cl. H01S 5/50; H01S 5/026; H01S 5/12; H01S 5/10

(52) U.S. Cl. CPC H01S 5/50; H01S 5/105; H01S 5/12; H01S 5/026

(57) ABSTRACT

A semiconductor optical amplifier is configured to provide output light with reduced optical chirp when pulsed. The semiconductor optical amplifier includes a waveguide and a diffraction grating positioned between a first semiconductor layer and a second semiconductor layer. The semiconductor optical amplifier emits output light through a two-dimensional surface of the first semiconductor layer or the second semiconductor layer. The diffraction grating may be a 1D or 2D photonic crystalline structure that directs light to the waveguide to facilitate amplification through constructive interference. The semiconductor optical amplifier is configured to support narrow line widths and single mode laser operations.

### CROSS REFERENCE TO RELATED APPLICATIONS

This application claims priority to U.S. provisional patent application No. 62/901,687 entitled, “High Peak-Power Single-Mode Semiconductor Lasers” filed Sep. 17, 2019, which is hereby incorporated by reference.

### BACKGROUND INFORMATION

Imaging devices are used in contexts such as healthcare, navigation, and security, among others. Imaging systems often measure radio waves or light waves to facilitate imaging. Imaging that measures light scattered by an object is especially challenging and advances to the devices, systems, and methods to improve optical imaging are sought to increase speed, increase resolution, reduce size and/or reduce cost. Some imaging systems require high-intensity light sources and may require laser light sources due to the specific features of laser light (e.g. spatial and/or temporal coherence). Other contexts may also require high-intensity laser light having particular high-power light requirements.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 illustrates a semiconductor optical device including a semiconductor optical amplifier, in accordance with aspects of the disclosure.

FIGS. 2A, 2B, 2C, and 2D illustrate various configurations of a semiconductor optical device and semiconductor optical amplifier, in accordance with aspects of the disclosure.

FIGS. 3A and 3B illustrate a surface-emitting laser configured to operate as an optical amplifier, in accordance with aspects of the disclosure.

FIGS. 4A and 4B illustrate example configurations of intermediate stages within a semiconductor optical amplifier, in accordance with aspects of the disclosure.

FIG. 5 illustrates a flow diagram of a process for operating a laser as a semiconductor optical amplifier, in accordance with aspects of the disclosure.

### DETAILED DESCRIPTION

Embodiments of a semiconductor optical device are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

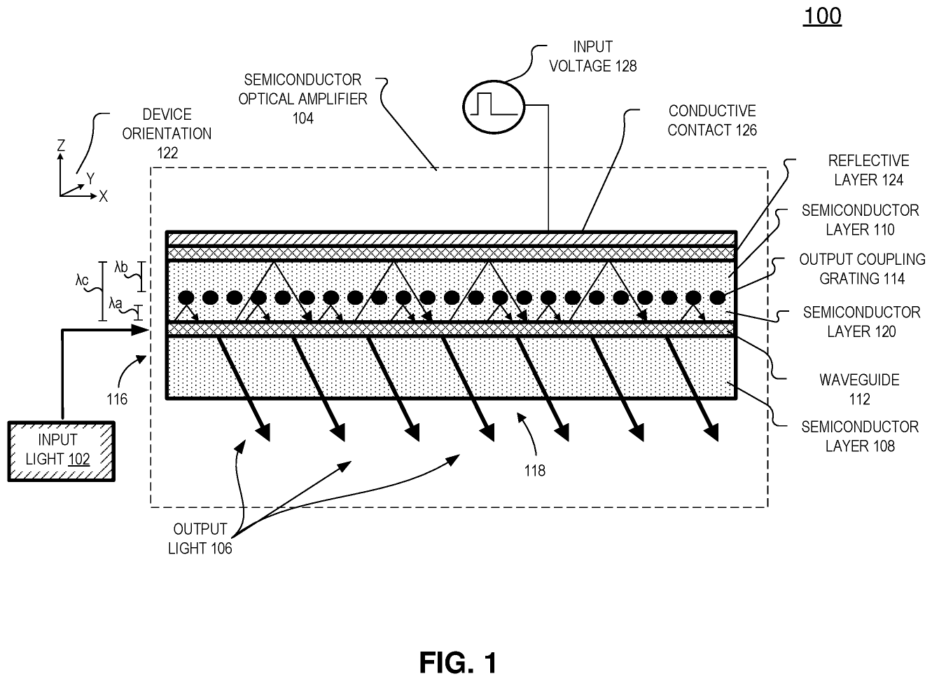

Disclosed herein are embodiments of a semiconductor optical amplifier configured to provide amplified output light with reduced or eliminated optical chirp, when the semiconductor optical amplifier is operated under a short time duration (i.e., is pulsed). Optical chirp may be described as a change in wavelength or frequency of light when the light is modulated or turned on and/or off. As a result, optical chirp may result in changes in various device parameters, such as device temperature, electron density, and the like. The disclosed semiconductor optical amplifier may be operated with pulses without exhibiting optical chirp, or may be operated with pulses that exhibit negligible or small amounts of chirp (e.g., less than 1 MHz/μs). To provide this robust operation, the semiconductor optical amplifier includes a waveguide and a diffraction grating. The waveguide and diffraction grating are disposed within a semiconductor substrate and may be positioned between two or more semiconductor layers. The semiconductor optical amplifier emits output light through a two-dimensional surface of the semiconductor substrate, which improves performance of the semiconductor optical amplifier under higher power operations. The diffraction grating may be a one-dimensional (“1D”) or two-dimensional (“2D”) photonic crystalline structure that facilitates constructive interference and deflects (or directs) light into the waveguide and/or out of the waveguide by constructive interference (e.g., by adding a grating vector to the lightwave vector). The semiconductor optical amplifier may support narrow line widths and single mode (e.g., single transverse mode) laser operations, according to an embodiment. These embodiments and others are described in more detail with references to FIGS. 1-5.

FIG. 1 illustrates a side view of a semiconductor optical device 100 that is configured to selectively amplify the intensity of received input light. The semiconductor optical device 100 includes input light 102 being injected into a semiconductor optical amplifier 104, to produce output light 106. Semiconductor optical amplifier 104 enables semiconductor optical device 100 to operate while providing output light 106 with narrow line widths, high output power, and a constant frequency with respect to time (i.e., no chirp), among other benefits. Semiconductor optical amplifier 104 may also enable single transverse mode operation.

Input light 102 is a seed light that is selectively maintained or amplified through semiconductor optical amplifier 104. Input light 102 may be a laser that is operating in the 700 nm to 980 nm wavelength range. Input light 102 could be ultraviolet, visible, or infrared. In aspects of this disclosure, visible light may be defined as having a wavelength range of approximately 380 nm-700 nm. Non-visible light may be defined as light having wavelengths that are outside the visible light range, such as ultraviolet light and infrared light. Infrared light having a wavelength range of approximately 700 nm-1 mm includes near-infrared light. In aspects of this disclosure, near-infrared light may be defined as having a wavelength range of approximately 800 nm-1.6 μm. Input light 102 may be injected into semiconductor optical amplifier 104 using a variety of configurations that are described in more detail hereafter.

Semiconductor optical amplifier 104 includes a variety of features that transform or amplify input light 102 into output light 106, while concurrently supporting pulsed operation, single transverse mode, and constant frequency with respect to time, according to various embodiments. Semiconductor optical amplifier 104 includes semiconductor layer 108, semiconductor layer 110, waveguide 112, and output coupling grating 114, according to an embodiment. Semiconductor layer 108 is a semiconductor substrate upon which waveguide 112 and/or output coupling grating 114 are formed. Semiconductor layer 108 may be doped (e.g., n-type or p-type) to facilitate operation of semiconductor optical amplifier 104.

Waveguide 112 is disposed between semiconductor layer 108 and semiconductor layer 110 and is configured to propagate light from an input region 116 to an output region 118 of semiconductor optical amplifier 104. Waveguide 112 may be fabricated using one or more of a variety of techniques, as are known in the art. Waveguide 112 may be fabricated using confinement structures. The center of the confinement structures is a waveguide core that may include one or more quantum wells. The quantum wells may have both low and intermediate band gaps. Quantum wells confine electrons and/or holes, and quantum wells (alone) are typically too thin for good light confinement. Therefore, waveguide 112 may include a layer of higher band gap material around the quantum wells. This surrounding and higher band gap layer forms the cladding of waveguide 112. A grating may then be positioned in the cladding or in the interface between the core (quantum wells) and cladding, and a grating may be arranged to have an amount of interaction with the guided light that enables deflection and redirection of guided light. In one particular embodiment, waveguide 112 is constructed by disposing a narrow bandgap material (e.g., 5-10 nm thick) into semiconductor layer 108. The narrow bandgap material creates a quantum well that confines electrons. The narrow bandgap material may be doped and annealed to intermix the dopants with the narrow bandgap material. The narrow band gap material may be partially surrounded with higher bandgap material (e.g., 100-200 nm thick) that is configured to confine propagating light by acting as a waveguide. N-type and p-type doping may be subsequently added to the waveguide in varying quantities to support or improve operational properties of waveguide 112. Semiconductor optical amplifier 104 includes a variety of features that amplify input light 102 into output light 106, while concurrently enabling pulsed operations, single transverse mode, and constant frequency with respect to time, according to various embodiments

Output coupling grating 114 is an optical element configured to increase the intensity of light such that output light 106 has a greater intensity (i.e., is amplified) than input light 102. Output coupling grating 114 directs light into waveguide 112. Output coupling grating 114 may direct light coming from waveguide 112 back to waveguide 112, and/or output coupling grating 114 may direct light from semiconductor layer 110 to waveguide 112. Output coupling grating 114 may be disposed or fabricated some predetermined optical distance λa away from waveguide 112 to cause constructive interference between light within waveguide 112 and light that is being directed to waveguide 112 from output coupling grating 114. In other words, output coupling grating 114 is an embedded grating, as opposed to a surface grating, according to one embodiment of the disclosure. A semiconductor layer 120 may be disposed between waveguide 112 and output coupling grating 114 to define the predetermined optical distance λa between waveguide 112 and output coupling grating 114. Optical distance λa may be a multiple a quarter wavelength of input light 102 (e.g., ¼, 2/4, ¾, etc. λ), according to an embodiment.

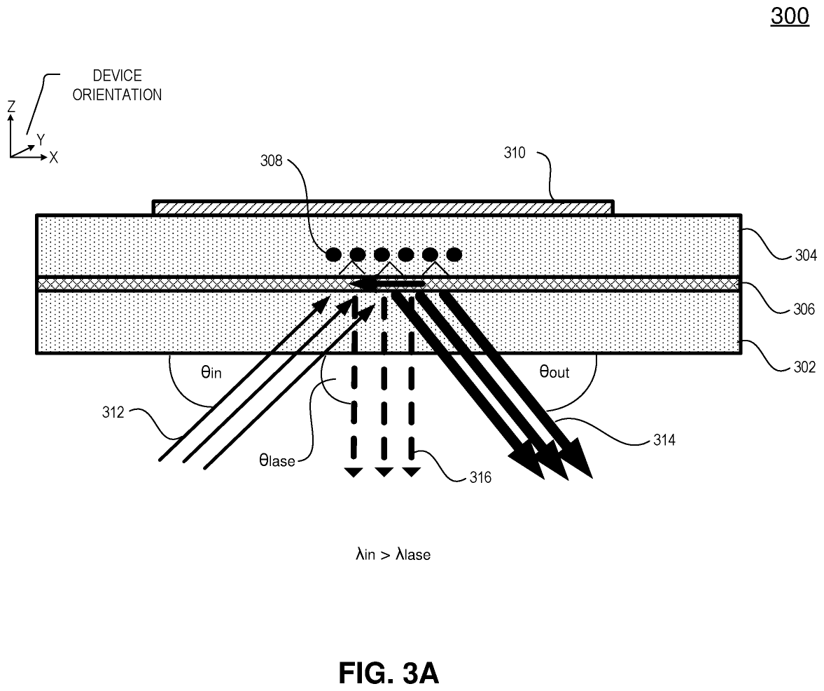

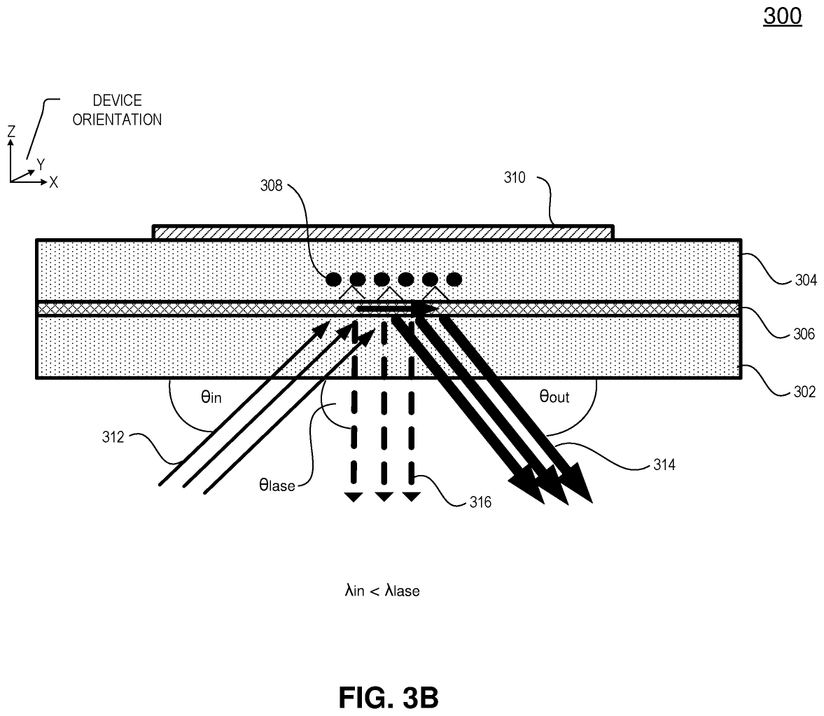

Output coupling grating 114 may be fabricated as a one dimensional (“1D”) diffraction grating or as a two dimension (“2D”) diffraction grating, according to various embodiments. Generally speaking, a 1D diffraction grating is periodic in one direction, and a 2D diffraction grating is periodic in two directions. Using the device orientation 122 as a reference, output coupling grating 114 may be constructed as a 1D diffraction grating and include a structure that is periodic along an x-axis of semiconductor optical amplifier 104. Using the device orientation 122 as a reference, output coupling grating 114 may be constructed as a 2D diffraction grating and include a structure that is periodic along the x-axis and the y-axis of semiconductor optical amplifier 104. According to one embodiment, output coupling grating 114 may be implemented as a 1D or 2D diffraction grating that is a photonic crystalline structure. The photonic crystalline structure may be configured to couple light in or out of waveguide 112 at the same wavelength (e.g., 700-950 nm) as input light 102, and quantum wells or quantum dots within waveguide 112 may amplify the intensity of input light 102 to generate output light 106, according to an embodiment. In a particular embodiment, described hereafter with reference to FIGS. 3A and 3B, a photonic crystalline structure may be configured to lase at a wavelength (e.g., 950 nm) that is different than input light 102 and may still be used to amplify input light 102 at the wavelength (e.g., 930 nm) of input light 102. In some embodiments, semiconductor optical device 100 may share similarities with a photonic crystal surface emitting laser (“PCSEL”).

Semiconductor optical amplifier 104 may include a reflective layer 124 and a conductive contact 126 to facilitate selectively amplifying the intensity of input light 102, into output light 106. Reflective layer 124 and conductive contact 126 are disposed upon or coupled to semiconductor layer 110. Reflective layer 124 is configured to direct light to waveguide 112. The light may be directed from waveguide 112 and/or from output coupling grating 114 back to waveguide 112. Conductive contact 126 may include a window to let light into semiconductor optical amplifier 104. Another conductive contact (not shown) may be disposed on the opposite side of semiconductor optical amplifier 104 (e.g., onto semiconductor layer 108) to, for example, provide a reference voltage.

Reflective layer 124 may be positioned an optical distance λb from output coupling grating 114. The optical distance λb may be a multiple of a quarter wavelength of input light 102. Reflective layer 124 may be configured to add a phase shift or wave shift to input light 102 or to light received from waveguide 112. Optical distance λb may also be defined based on a wave shift created by reflective layer 124. The incident angle of input light 102 may vary the design and fabrication of the optical distances λa and λb. In one embodiment, a thickness of semiconductor layer 110 (or the thickness of multiple semiconductor layers) causes the phase of the reflected light to be in phase with the light that is deflected downward by output coupling grating 114. In another embodiment, the thickness of semiconductor layer 110 and semiconductor layer 120 is defined so that reflective layer 124 is an optical distance λc from waveguide 112, which may phase shift input light 102 by a multiple of a wavelength, to facilitate constructive interference in waveguide 112. Output coupling grating 114 deflects light upward from waveguide 112, toward reflective layer 124, and downward away from reflective layer 124. These two beams combine in constructive interference. The relative delay of one beam to another is typically a multiple of the wavelength (lambda) of the light, in one embodiment. To support constructive interference operation, the light coming from reflective layer 124 and light coming from output coupling grating 114 are typically delayed or phase-shifted by a multiple of the wavelength of the light. One way to express the constructive interference is:

2*λb*cos(α)+wave_shift_reflector=n*wavelength,

where:

λb— is the wavelength,

α—is the angle between the deflected light beams in the semiconductor layers and z,

wave_shift_reflector—is a phase shift caused by the reflective layer, and

n*wavelength—is a multiple of the wavelength of the beams of light.

Reflective layer 124 may be a light reflective dielectric (e.g., distributed Bragg reflect “DBR”). The function of the reflective layer 124 may be combined with conductive contact 126, so that reflective layer 124 and conductive contact 126 are combined into a single layer, according to an embodiment. Conductive contact 126 may be implemented as gold, silicon mononitride, silicon nitride, or some of conductive and reflective material used in semiconductor manufacturing.

An input voltage 128 may be coupled to conductive contact 126 to electrically operate semiconductor optical amplifier 104. Input voltage 128 may provide a first voltage (e.g., <1.5 V) to conductive contact 126 to enable input light 102 to pass through waveguide 112 unamplified or attenuated, according to an embodiment. Input voltage 128 may be configured to apply a second voltage level (e.g., 1.5-3.3 V) that pumps current into the semiconductor optical amplifier 104 and that generates output light 106 with an intensity that is greater than the intensity of input light 102. Input voltage 128 may be configured to switch voltage levels from a first voltage level to a second (higher) voltage level in pulses that may be as short as 1-3 μs in duration for some applications and may be in the nanosecond or picosecond range for Light Detection and Ranging (“LIDAR”). The configuration of semiconductor amplifier 104 enables pulse-based amplification of input light 102 without change in light frequency with respect to time (i.e., chirp), according to embodiments of the disclosure.

Semiconductor optical amplifier 104 may operate with a number of advantages that are deficient in existing technologies. Pulsing a continuous wave laser may cause chirping, a phenomenon where the width of a desired wavelength expands and encompasses undesired wavelengths, so that undesirable wavelengths are concurrently emitted or generated in output light 106. Furthermore, semiconductor optical amplifier 104 is capable of emitting output light 106 in a single mode (e.g., single transverse and single longitudinal mode) of operation, whereas existing amplifiers tend to emit dual or greater mode output light upon amplification. In one embodiment, output light 106 has a line-width of 1 nm or less and has a wavelength between 680 nm and 1000 nm, and semiconductor optical amplifier 104 may operate with a power in the range of 1-50 Watts, or higher.

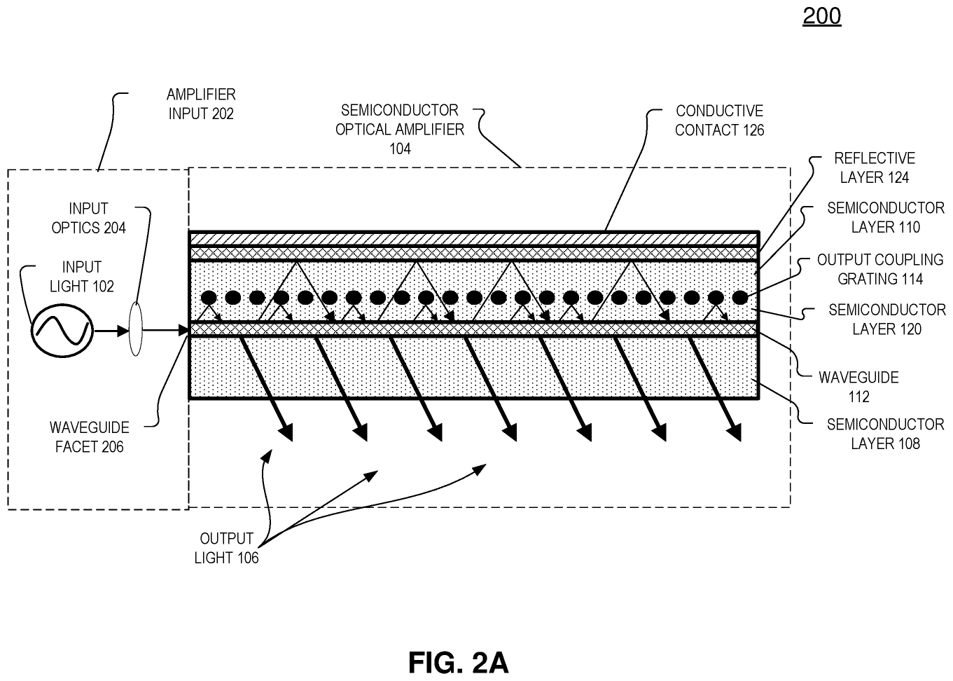

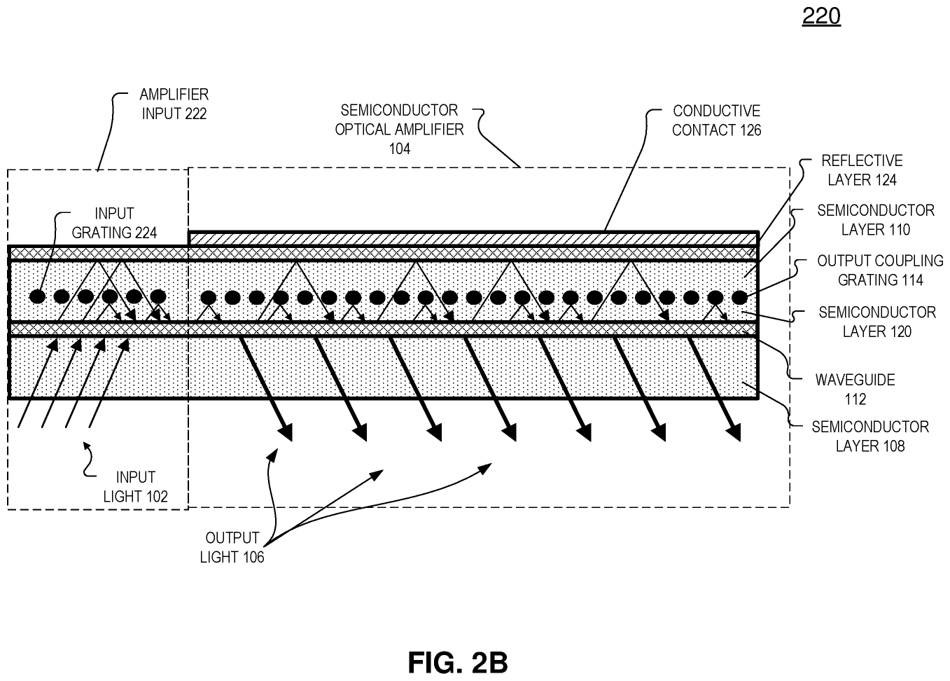

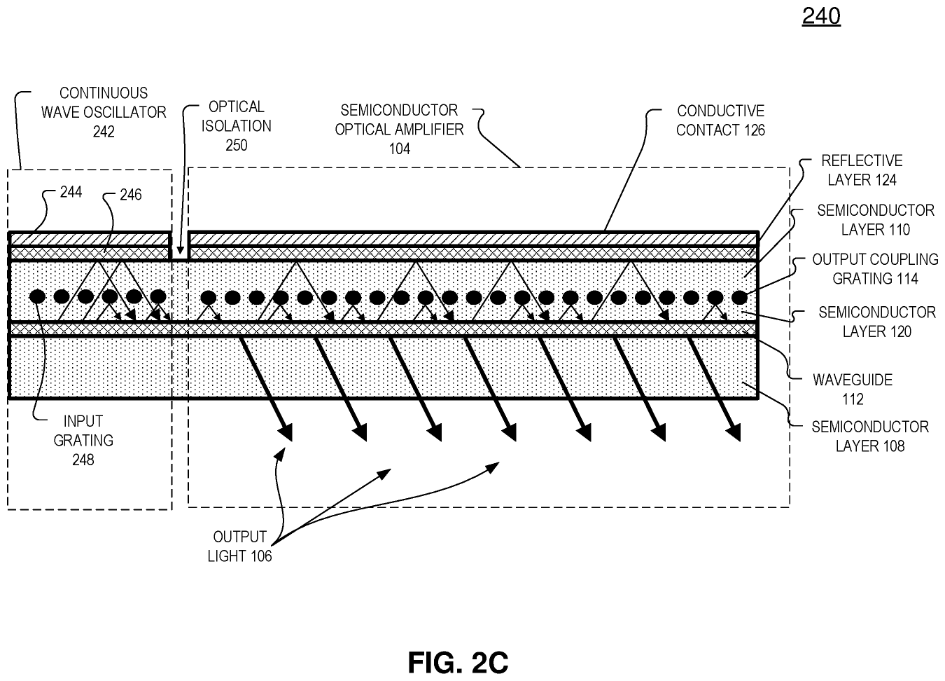

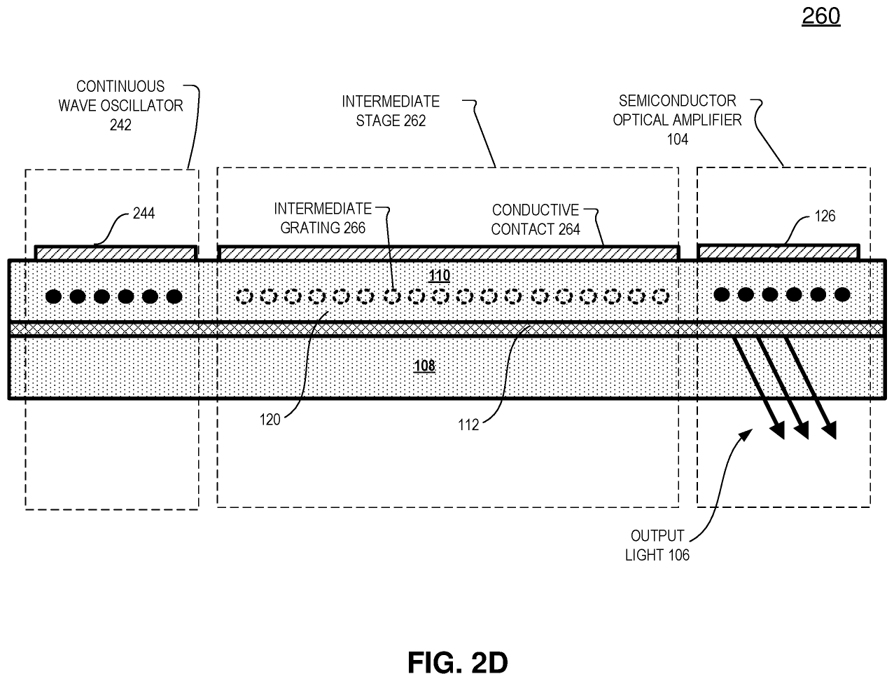

FIGS. 2A, 2B, 2C, and 2D illustrate various amplifier input configurations that may be used to generate the amplified output light 106, according to various embodiments.

FIG. 2A illustrates a direct injection configuration for a semiconductor optical device 200, according to an embodiment. Semiconductor optical device 200 includes an amplifier input 202 coupled to semiconductor optical amplifier 104, according to an embodiment. Amplifier input 202 includes input light 102 and input optics 204 configured to insert input light 102 into waveguide facet 206. Input optics 204 may be used to focus input light 102 onto a small area, such as the height of waveguide 112. Waveguide 112 may have a thickness or waveguide facet 206 that is 0.1-5 μm in height.

FIG. 2B illustrates a semiconductor optical device 220, according to an embodiment. Semiconductor amplifier device 104 includes an amplifier input 222 coupled to semiconductor optical amplifier 104, according to an embodiment. Amplifier input 222 includes input grating 224 and layers (e.g., 108, 110, 112, 120, etc.) of semiconductor optical amplifier 104, which are configured (in combination) to direct input light 102 to waveguide 112, according to an embodiment. In this configuration, input light 102 may be injected into amplifier input 222 at an angle toward the right (as shown) or towards the left (not shown) and from the bottom (e.g., through semiconductor layer 108) of semiconductor optical amplifier 104. Input light 102 may alternatively be injected into amplifier input 222 at an angle and from the top (e.g., through semiconductor layer 110) of semiconductor optical amplifier 104.

FIG. 2C illustrates a semiconductor optical device 240, according to an embodiment. Semiconductor optical device 240 includes a continuous wave oscillator 242 coupled to semiconductor amplifier device 104. Continuous wave oscillator 242 is configured to generate light and direct the light onto waveguide 112. Continuous wave oscillator 242 shares semiconductor layers 108, 110, 120 with semiconductor optical amplifier 104, according to an embodiment.

Continuous wave oscillator 242 also includes a conductive contact 244, a reflective layer 246, and an input grating 248 optically isolated from semiconductor optical amplifier 104, according to an embodiment. Conductive contact 244 and reflective layer 246 may be integrated into a single layer. Conductive contact 244 receives a voltage that operates continuous wave oscillator 242, e.g., a DC voltage. Reflective layer 246 is configured to direct light onto waveguide 112. Input grating 248 is positioned between semiconductor layer 110 and waveguide 112 and is configured to direct light onto waveguide 112.

Optical isolation 250 may be used to optically isolate continuous wave oscillator 242 from semiconductor optical amplifier 104. Optical isolation 250 may include a gap between conductive contact 126 and conductive contact 244 and may provide electrical isolation, if the trench is wide enough and/or deep enough. Optical isolation 250 may also include dopants and/or structures disposed between continuous wave oscillator 242 and semiconductor optical amplifier 104 to reduce backscatter from semiconductor optical amplifier 104 to continuous wave oscillator 242. In some implementations, anti-reflection coating may be added on facets of the device, or unpumped sections may be fabricated near the facets to absorb light and reduce reflection within semiconductor optical device 240.

Semiconductor optical device 240 resolves existing problems in the semiconductor laser technology field by providing an amplifier that may be pulsed while maintaining a single mode of operation, narrow line widths, and reduced and/or eliminated chirp, according to various embodiments disclosed herein.

FIG. 2D illustrates a semiconductor optical device 260, according to an embodiment. Semiconductor optical device 260 includes an intermediate stage 262 positioned between semiconductor optical amplifier 104 and continuous wave oscillator 242, according to an embodiment. Intermediate stage 262 includes a conductive contact 264, semiconductor layer 108, semiconductor layer 110, waveguide 112, and semiconductor layer 120. Intermediate stage 262 may be configured to inject current into light that is propagating through waveguide 112 by receiving one or more voltage levels at conductive contact 264. Intermediate stage 262 may be used to compensate for temperature changes of continuous wave oscillator 242. Waveguide 112 within intermediate stage 262 may also be configured to not induced gain or absorption and simply heat semiconductor optical device 260. In one embodiment, conductive contact 264 is configured as an isolated or non-isolated heater. Intermediate stage 262 may be operated in a pass-through mode where light is permitted to propagate with minor changes in intensity, or intermediate stage 262 may be operated in an amplifier mode where light propagating through waveguide 112 increases in intensity at least partially based on voltage levels received at conductive contact 264. Intermediate stage 262 may be configured to amplify light intensity, attenuate light intensity, phase shift light passing through, and/or allow light to pass through without change in intensity, according to various embodiments. Optionally, intermediate stage 262 may include an intermediate grating 266 to support further light deflection of light propagating through intermediate stage 262. Intermediate grating 266 may be configured as a one-dimensional or two-dimensional diffraction grating, according to various embodiments. Intermediate stage 262 may be used to control the phase of light passing through. Intermediate stage 262 may be configured to control the phase of the light by changing the temperature of intermediate stage 262, by injecting current into intermediate stage 262, and/or by applying a voltage (e.g., a reverse voltage) into intermediate stage 262, as examples. Intermediate stage 262 may have a waveguide portion with a modified bandgap that causes light to phase shift as the light passes through intermediate stage 262.

FIGS. 3A and 3B illustrate configurations for operating a laser as a semiconductor optical amplifier, according to embodiments of the disclosure. FIG. 3A illustrates a laser 300 configured to operate as a semiconductor optical amplifier, according to an embodiment of the disclosure. Laser 300 is configured as a secondary or slave laser that receives and amplifies light from one or more primary or master lasers. While operating as a laser, laser 300 generates (or lases) light 316 at a lasing wavelength λlase. Laser 300 generates light 316 at an angle θlase with respect to the body (or substrate) of laser 300. Although laser 300 may be fabricated to lase at lasing wavelength λlase, laser 300 may be concurrently operated as a semiconductor optical amplifier of light at another wavelength, according to an embodiment of the disclosure.

Laser 300 includes a semiconductor layer 302, a semiconductor layer 304, a waveguide 306, and a diffraction grating 308, according to an embodiment of the disclosure. The various layers of laser 300 may constitute the body of laser 300. Waveguide 306 and diffraction grating 308 are disposed between semiconductor layer 302 and semiconductor layer 304. Laser 300 also includes a conductive contact 310 that is configured to receive one or more voltage levels that control the operation of laser 300. Laser 300 may include an emission side contact (not shown) that may have a window to allow light to pass through and that is configured to receive, for example, a reference voltage.

Laser 300 receives input light 312 at an incident angle θin and outputs output light 314 at a reflected angle ° out. Incident angle θin is equal to reflected angle θout, according to an embodiment. If input light 312 has an input wavelength λin that is longer than a lasing wavelength λlase of lase light 316, then waveguide 306 is predominately excited against the direction of input light 312 (e.g., along the negative x axis of laser 300). The angle θlase may be referenced as a first angle, and the incident angle θin may be referenced as a second angle.

The operational configuration of laser 300 may provide a variety of advantages to the field of semiconductor lasers. Some advantages may include low optical chirp, spatial mode operations that are defined by the mode of input light 312 (the seed), single transverse mode gain for output light 314 (even if laser 300 lases in multiple transverse modes), and surface area transmission rather than facet-based transmission, among others.

FIG. 3B illustrates laser 300 waveguide operation when input light 312 has an input wavelength λin that is shorter than a lasing wavelength λlase of laser 300. If input wavelength λin is shorter than a lasing wavelength λlase of lase light 316, then waveguide 306 may be predominately excited in the direction of input light 312 (e.g., along the positive x axis of laser 300).

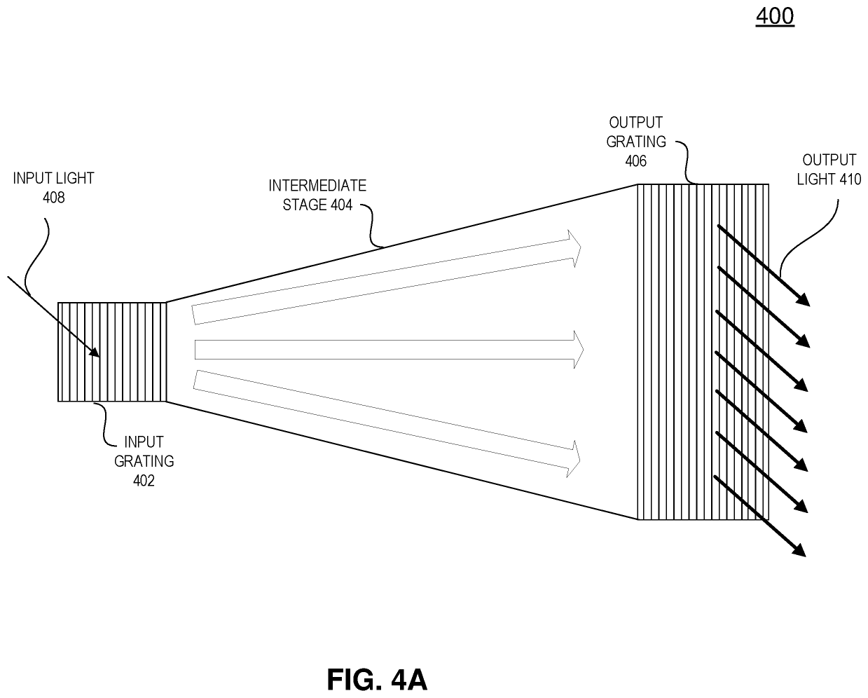

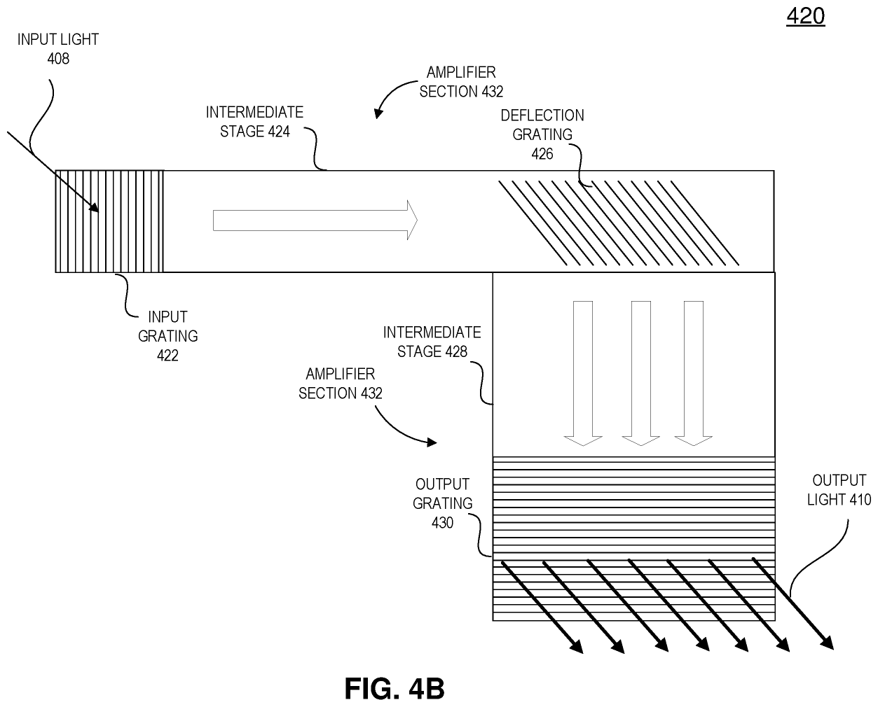

FIGS. 4A and 4B illustrate configurations of intermediate stages of semiconductor optical amplifiers, according to embodiments of the disclosure. FIG. 4A illustrates a semiconductor optical device 400 that is configured to withstand and deliver high power amplified light, e.g., in excess of 5 W. Semiconductor optical device 400 may be a top view of semiconductor optical device 100, 200, 220, 240, or 260. Semiconductor optical device 400 includes an input grating 402, an intermediate stage 404, and an output grating 406, according to an embodiment. Intermediate stage 404 may be tapered to increase in width from input grating 402 to output grating 406. The input grating 402 may be configured to receive input light 408, and output grating 406 may be configured to emit output light 410 at a higher (amplified) intensity than input light 408.

FIG. 4B illustrates a semiconductor optical device 420 that is configured to withstand and produce high-powered amplified light. Semiconductor optical device 420 may be a top view of semiconductor optical device 100, 200, 220, 240, or 260. Semiconductor optical device 420 includes an input grating 422, an intermediate stage 424, a deflection grating 426, an intermediate stage 428, and an output grating 430, according to an embodiment. Input grating 422 may be configured to receive input light 408, and output grating 430 may be configured to emit output light 410 at a higher (amplified) intensity than input light 408. Intermediate stage 424 may be part of a first amplifier section 432, and intermediate stage 428 may be part of a second amplifier section 434. The second amplifier section 434 may be orthogonal to the first amplifier section 432, to receive light from deflection grating 426.

The intermediate stages of FIGS. 4A and 4B may be configured to amplify light intensity, attenuate light intensity, phase shift light passing through, and/or allow light to pass through without change in intensity, according to various embodiments. According to one embodiment, one or more of the gratings 402, 406, 422, 426, 430 of FIGS. 4A and 4B may be implemented as surface gratings (rather than embedded gratings).

The configurations of semiconductor optical devices 400 and 420 may provide a number of advantages. Some of the advantages include: surface emissions may improve mode quality, the gratings may be tuned to prevent lasing and back reflection, emission of amplified light through the surface allows for scaling to higher power since the devices are not limited by facet power density, among other advantages.

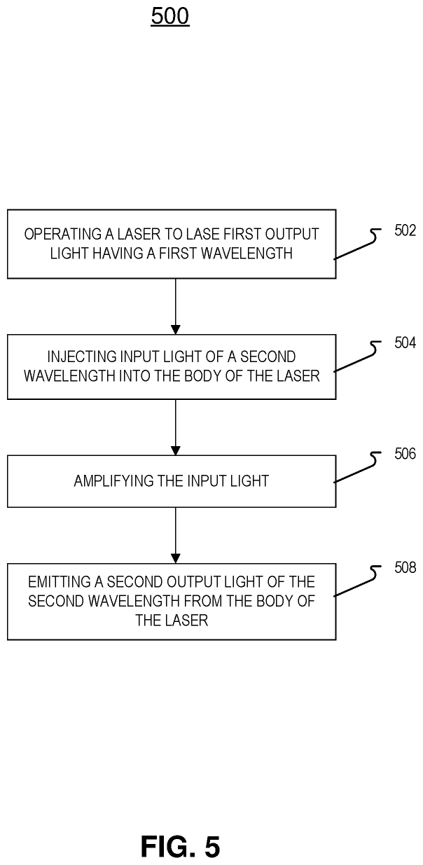

FIG. 5 illustrates a flow diagram of a process 500 of amplifying light, according to embodiments of the disclosure.

At operation 502, process 500 includes operating a laser to lase first output light having a first wavelength, according to an embodiment. The first output light exits a body (e.g., a substrate) of the laser at a first angle, according to an embodiment.

At operation 504, process 500 includes injecting input light of a second wavelength into the body of the laser, according to an embodiment. The input light being injected into the body of the laser at a second angle, according to an embodiment.

At operation 506, process 500 includes amplifying the input light, according to an embodiment. To amplify the input light, the laser includes and utilizes a waveguide and a diffraction grating positioned between a first semiconductor layer and a second semiconductor layer, according to an embodiment. The waveguide and diffraction grating may be configured similarly to those in any of the semiconductor optical devices of FIG. 1, 2A, 2B, 2C, or 2D, according to various embodiments.

At operation 508, process 500 includes emitting a second output light of the second wavelength from the body of the laser, according to an embodiment. Emitting the second output light includes emitting the output light at a greater intensity than the input light and at the second angle, with respect to the body of the laser, according to an embodiment.

In process 500, the first output light may be filtered while the second output light is utilized. Since the first output light exits the laser body at a first angle and the second output light exits the laser body at a second angle, an optical system (e.g., a lens) may be positioned to receive the second output light and to not receive the first output light. Alternatively or additionally, a filter may be positioned proximate to the output of the laser to filter out the wavelength of the first output light while passing or transmitting the wavelength of the second output light. Other techniques may be implemented to filter and transmit output light from the laser, according to various embodiments of the disclosure.

The above description of illustrated embodiments of the invention, including what is described in the λbstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A semiconductor optical device, comprising:
a first semiconductor layer;
a second semiconductor layer;
a waveguide to receive input light, wherein the waveguide is positioned between the first semiconductor layer and the second semiconductor layer; and
a diffraction grating positioned between the first semiconductor layer and the second semiconductor layer, wherein the diffraction grating is configured to deflect the input light into and out of the waveguide.

2. The semiconductor optical device of claim 1, wherein the input light is infrared light.

3. The semiconductor optical device of claim 1, wherein the diffraction grating includes structures, wherein the structures periodically repeat along a first dimension of the semiconductor optical device, or the structures periodically repeat along the first dimension of the semiconductor optical device and along a second dimension of the semiconductor optical device.

4. The semiconductor optical device of claim 1, wherein the diffraction grating includes a photonic crystalline structure.

5. The semiconductor optical device of claim 1 further comprising:
an input coupling diffraction grating disposed between the first semiconductor layer and the second semiconductor layer, wherein the input coupling diffraction grating is configured to direct the input light to the waveguide.

6. The semiconductor optical device of claim 5 further comprising:
a non-grated optical amplifier disposed between the input coupling diffraction grating and the diffraction grating, wherein the non-grated optical amplifier includes a bias contact coupled to the second semiconductor layer and a reference contact coupled to the first semiconductor layer, wherein the waveguide extends from the input coupling diffraction grating through the non-grated optical amplifier to the diffraction grating.

7. The semiconductor optical device of claim 5 further comprising:
an intermediate stage disposed between the input coupling diffraction grating and the diffraction grating, wherein the intermediate stage includes a width dimension that increasingly tapers from the input coupling diffraction grating to the diffraction grating, wherein the intermediate stage is configured to selectively provide thermal isolation and/or optical amplification between the input coupling diffraction grating and the diffraction grating.

8. The semiconductor optical device of claim 1, wherein the waveguide includes a first waveguide having a first width and includes a second waveguide having a second width that is greater than the first width, wherein the semiconductor optical device further comprises:
an intermediate diffraction grating positioned between the first waveguide and the second waveguide, wherein the intermediate diffraction grating is configured to diffract the input light from the first waveguide to the second waveguide.

9. The semiconductor optical device of claim 1 further comprising:
a reflective layer coupled to the second semiconductor layer, wherein a distance between the reflective layer and the waveguide is a multiple of a quarter of a wavelength of the input light.

10. The semiconductor optical device of claim 9, wherein the reflective layer is configured to phase shift reflected light to align with a phase of other light that is directed towards the waveguide.

11. The semiconductor optical device of claim 1, wherein amplified light exits the first semiconductor layer proximate to the diffraction grating through a two-dimensional surface of the first semiconductor layer.

12. A semiconductor optical amplifier comprising:
a semiconductor substrate;
an optical waveguide having an optical input configured to receive light, wherein the optical waveguide is within the semiconductor substrate; and
a two-dimensional photonic structure coupled with the optical waveguide, wherein the two-dimensional photonic structure is configured to outcouple amplified light through a two-dimensional area of the semiconductor substrate.

13. The semiconductor optical amplifier of claim 12, the amplified light is amplified seed light outcoupled by the two-dimensional photonic structure at a first output angle, and wherein the two-dimensional photonic structure is also configured to outcouple lasing light at a second output angle.

14. The semiconductor optical amplifier of claim 12, wherein at least a portion of the semiconductor substrate is layered above and below the two-dimensional photonic structure to embed the two-dimensional photonic structure within the semiconductor substrate.

15. The semiconductor optical amplifier of claim 12, wherein a frequency of operation of the semiconductor optical amplifier is at least partially determined by a spacing between the optical waveguide and the two-dimensional photonic structure.

16. The semiconductor optical amplifier of claim 12, wherein the optical waveguide is disposed a predetermined distance from the two-dimensional photonic structure, wherein the predetermined distance is a multiple of a quarter of a wavelength of a frequency of the input to be received and amplified.

17. The semiconductor optical amplifier of claim 12 further comprising:
an input grating configured to incouple the light onto the optical waveguide through an input two-dimensional area of the semiconductor substrate.

18. A method of operating a laser device comprising:
operating a laser to lase first output light having a first wavelength;
injecting input light of a second wavelength into a body of the laser;
amplifying the input light; and
emitting a second output light of the second wavelength from the body of the laser.

19. The method of claim 18, wherein amplifying the input light includes using a waveguide and a diffraction grating, wherein the waveguide and the diffraction grating are positioned between a first semiconductor layer and a second semiconductor layer.

20. The method of claim 18, wherein injecting the input light of a second wavelength includes injecting the input light at a first angle to cause the second output light to be emitted at the first angle, wherein the first angle is less than an emission angle of the first output light.
